(19) United States
(12) Patent Application Publication
(10) Pub. No.: US 2014/0182908 A1
(43) Pub. Date: Jul. 3, 2014

(54) EPOXY RESIN COMPOSITION FOR INSULATING FILM, INSULATING FILM, AND PRINTED CIRCUIT BOARD HAVING THE SAME

(71) Applicant: SAMSUNG ELECTRO-MECHANICS CO., LTD., Suwon (KR)

(72) Inventors: Ji Hye Shim, Suwon (KR); Yong Jin Park, Suwon (KR); Hwa Young Lee, Suwon (KR); Hyung Mi Jung, Suwon (KR)

(73) Assignee: Samsung Electro-Mechanics Co., Ltd., Suwon (KR)

(21) Appl. No.: 13/837,933

(22) Filed: Mar. 15, 2013

(30) Foreign Application Priority Data
Dec. 28, 2012 (KR) 10-2012-0157125

(51) Int. Cl. H05K 1/03; B29D 7/01; H05K 1/02

(52) U.S. Cl. CPC H05K 1/0373; H05K 1/0271; B29D 7/01
USPC 174/258; 523/427; 428/339; 264/233

(57) ABSTRACT

This invention relates to an epoxy resin composition for an insulating film, an insulating film, and a printed circuit board including the same. Particularly in a printed circuit board using a build-up process, a skin layer and a roughness are formed on the surface of the insulating film using different curing starting temperatures, so that peel strength can be enhanced, thus enabling the formation of a fine pattern, and also, a coefficient of thermal expansion of the insulating film is low, thus preventing the deformation of the film.

### CROSS-REFERENCE TO RELATED APPLICATION

This application claims the benefit of Korean Patent Application No. 10-2012-0157125, filed Dec. 28, 2012, entitled “Epoxy resin composition for insulating film, insulating film, and printed circuit board having the same,” which is hereby incorporated by reference in its entirety into this application.

### BACKGROUND OF THE INVENTION

1. Technical Field

The present invention relates to an epoxy resin composition for an insulating film, an insulating film, and a printed circuit board including the same.

2. Description of the Related Art

Printed circuit boards (PCBs) are typically manufactured in the form of a multilayer by electrically insulating inner Cu circuits using a polymer composite material. In order to normally operate PCBs and ensure reliability, adhesion between an insulating layer and a Cu layer is regarded as important. Sufficient adhesion is ensured by using methods of forming an appropriate roughness on the surface of the insulating layer to increase the surface area, as well as adding a component having high bondability with Cu to the insulating layer.

Multilayer PCBs are manufactured using known methods in such a manner that, as an insulating layer, glass fibers are impregnated with epoxy resin and cured, thus preparing prepreg sheets, which are then laminated on an inner circuit board having Cu foil circuits by means of a press, and through-holes are formed so as to achieve interlayer connection. However, such methods are problematic because high manufacturing costs are caused due to large-scale equipment being required, performing lamination using hot pressing takes a long period of time, and the through-holes are plated on the outer layer and thus Cu becomes thick, making it difficult to form a fine pattern.

With the goal of solving these problems, to manufacture multilayer PCBs using a build-up process, the development of manufacturing techniques including alternately forming conductor layers and organic insulating layers (or insulating films) of the circuit board is ongoing these days.

Typically, the manufacture of a multilayer PCB using a build-up process includes forming an inner circuit, laminating a build-up film, thus forming an insulating layer, followed by performing pre-curing→drilling→desmearing→electroless plating→electroplating→post-curing, thus forming an outer circuit. As such, a desmearing process using an acid solution is essential to remove smears from the insulating film, so that roughness is formed on the surface of a film using chemical treatment in the desmearing process. In this case, the surface of the cured insulating layer partially corrodes, thus forming a roughness. The adhesion between the insulating layer and the plating layer resulting from a plating process is affected by the roughness formed in the desmearing process depending on the curability of the film upon pre-curing, and is disadvantageous because it may be remarkably lower than adhesion resulting from hot pressing of the prepreg and the Cu foil.

To solve these problems, Patent Literature 1 discloses a method of forming a roughness after performing desmearing following mixing an epoxy resin with a thermoplastic resin to induce phase separation, but is problematic because the use of the thermoplastic resin may deteriorate properties including heat resistance, chemical resistance, etc. Also, Patent Literature 2 discloses easy formation of small surface irregularities via thermosetting of a resin composition including a polyfunctional epoxy resin, a phenol curing agent containing a triazine structure, and a rubber component, but may increase a coefficient of thermal expansion (CTE) of the insulating film due to the addition of the rubber component, undesirably deforming the substrate. Furthermore, after pre-curing and desmearing of the build-up film containing the inorganic filler in an increased amount to decrease CTE of the insulating film, the case where the inorganic filler is exposed to the surface of the film may weaken adhesion to the Cu plating layer which is subsequently formed via plating, and may cause defects such as delamination upon evaluation of reliability.
Patent Literature 1: Korean Unexamined Patent Publication No. 2004-0036219
Patent Literature 2: Korean Unexamined Patent Publication No. 1998-081447

### SUMMARY OF THE INVENTION

Culminating in the present invention, intensive and thorough research with the aim of solving the problems occurring in the related art resulted in the finding that when a mixture of a first epoxy resin having high curing reactivity and a low curing starting temperature (which is a first curing temperature) and a second epoxy resin having low curing reactivity and a high curing starting temperature (which is a second curing temperature) is sequentially subjected to primary curing and secondary curing at the first curing temperature and the second curing temperature, the second epoxy resin may slide out on the surface of the cured first epoxy resin upon secondary curing, thus forming a fine roughness of spheres having a size from hundreds of nm to about 1 μm, thereby obtaining improved peel strength and superior CTE of the substrate.

Accordingly, a first aspect of the present invention is to provide an epoxy resin composition for an insulating film, which may have low CTE and superior peel strength.

A second aspect of the present invention is to provide a method of manufacturing an insulating film having low CTE and superior peel strength.

A third aspect of the present invention is to provide an insulating film, which may be manufactured using the above method so as to enable the formation of a fine circuit pattern using plating.

A fourth aspect of the present invention is to provide a PCB including the insulating film.

In order to accomplish the above first aspect of the present invention, an epoxy resin composition for an insulating film (hereinafter, referred to as “the first invention”) is provided, which includes a thermosetting first epoxy resin having a curing starting temperature of 75˜100° C.; a thermosetting second epoxy resin having a curing starting temperature of 100˜150; a first curing agent for the first epoxy resin; a second curing agent for the second epoxy resin; and silica surface-treated with silane, wherein the curing starting temperature of the first epoxy resin is lower than the curing starting temperature of the second epoxy resin.

In the first invention, the epoxy resin composition may include 5˜15 wt % of the first epoxy resin, 5˜15 wt % of the second epoxy resin, 5˜20 wt % of the first curing agent, 5˜20 wt % of the second curing agent, and 50˜80 wt % of the silica surface-treated with silane.

In the first invention, the curing starting temperature of the first epoxy resin may be 75˜85° C., and the curing starting temperature of the second epoxy resin may be 120˜150° C.

In the first invention, the first epoxy resin may include one or more selected from the group consisting of a naphthalenic epoxy resin, a naphthol-phenolic epoxy resin, an olefinic epoxy resin, a diglycidyl ether of bisphenol A (DGEBA)-based epoxy resin having a molecular weight of 300 or less, and a diglycidyl ether of bisphenol F (DGEBF)-based epoxy resin having a molecular weight of 300 or less, and the second epoxy resin may include one or more selected from the group consisting of a cresol novolac epoxy resin, a bisphenol A epoxy resin, and a rubber modified epoxy resin.

In the first invention, a difference in the curing starting temperature between the first epoxy resin and the second epoxy resin may be 10˜70° C.

In the first invention, the first curing agent may be a triazine novolac curing agent having a secondary or tertiary amine group, and the second curing agent may be a phenol novolac curing agent.

In the first invention, the silica surface-treated with silane may be obtained by surface-treating silica with 0.5˜5 wt % of silane based on the weight of silica.

In order to accomplish the above second aspect of the present invention, a method of manufacturing an insulating film (hereinafter, referred to as “the second invention”) is to provided, which includes mixing a thermosetting first epoxy resin having a curing starting temperature of 75˜100° C., a thermosetting second epoxy resin having a curing starting temperature of 100˜150, a first curing agent for the first epoxy resin, a second curing agent for the second epoxy resin, and silica surface-treated with silane, thus preparing an epoxy resin composition; forming the composition into a film, and performing primary curing at 75˜100° C. and secondary curing at 100˜150° C.; and subjecting the film to desmearing to form a roughness.

In the second invention, each of the primary curing and the secondary curing may be performed for 10˜40 min.

In the second invention, the epoxy resin composition may include 5˜15 wt % of the first epoxy resin, 5˜15 wt % of the second epoxy resin, 5˜20 wt % of the first curing agent, 5˜20 wt % of the second curing agent, and 50˜80 wt % of the silica surface-treated with silane.

In the second invention, the curing starting temperature of the first epoxy resin may be 75˜85° C., and the curing starting temperature of the second epoxy resin may be 120˜150° C.

In the second invention, the first epoxy resin may include one or more selected from the group consisting of a naphthalenic epoxy resin, a naphthol-phenolic epoxy resin, an olefinic epoxy resin, a diglycidyl ether of bisphenol A (DGEBA)-based epoxy resin having a molecular weight of 300 or less, and a diglycidyl ether of bisphenol F (DGEBF)-based epoxy resin having a molecular weight of 300 or less, and the second epoxy resin may include one or more selected from the group consisting of a cresol novolac epoxy resin, a bisphenol A epoxy resin, and a rubber modified epoxy resin.

In the second invention, a difference in the curing starting temperature between the first epoxy resin and the second epoxy resin may be 10˜70° C.

In the second invention, the first curing agent may be a triazine novolac curing agent having a secondary or tertiary amine group, and the second curing agent may be a phenol novolac curing agent.

In the second invention, the silica surface-treated with silane may be obtained by surface-treating silica with 0.5˜5 wt % of silane based on a weight of silica.

In order to accomplish the above third aspect of the present invention, an insulating film (hereinafter, referred to as “the third invention”) is provided, which includes a bottom layer, and a surface skin layer formed to a thickness of 10˜200 nm on the bottom layer, wherein the silica content of the surface skin layer is 60 or less as a weight ratio based on 100 of the silica content of the bottom layer.

In the third invention, the silica content of the surface skin layer may be 40 or less as a weight ratio based on 100 of the silica content of the bottom layer.

In order to accomplish the above fourth aspect of the present invention, a PCB is provided, which includes the above insulating film.

### BRIEF DESCRIPTION OF THE DRAWINGS

The above and other aspects, features and other advantages of the present invention will be more clearly understood from the following detailed description when taken in conjunction with the accompanying drawings, in which:

FIG. 1 is a schematic view illustrating a mechanism for forming a surface skin layer on an insulating film using a stepped curing reaction according to the present invention;

FIG. 2 is a scanning electron microscope (SEM) image illustrating the surface of an insulating film manufactured in an example according to the present invention, after a pre-curing process;

FIG. 3 is an SEM image illustrating the cross-section of the insulating film manufactured in the example according to the present invention, after a pre-curing process; and

FIG. 4 is an SEM image illustrating the cross-section of an insulating film manufactured in a comparative example according to the present invention, after a pre-curing process.

### DESCRIPTION OF SPECIFIC EMBODIMENTS

Before the present invention is described in more detail, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention. It is noted that, the embodiments of the present invention are merely illustrative, and are not construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related with the present invention may make the gist of the present invention unclear, a detailed description thereof will be omitted.

The present invention pertains to, in a multilayer PCB including conductor circuit layers and insulating layers which are alternately stacked using a build-up process, an epoxy resin composition for interlayer insulation, which is able to form a surface skin layer and a roughness via thermosetting at different curing starting temperatures, an insulating film manufactured using the resin composition and a manufacturing method thereof, and a PCB including multiple layers by insulating inner Cu circuits using the above insulating film as an insulating layer.

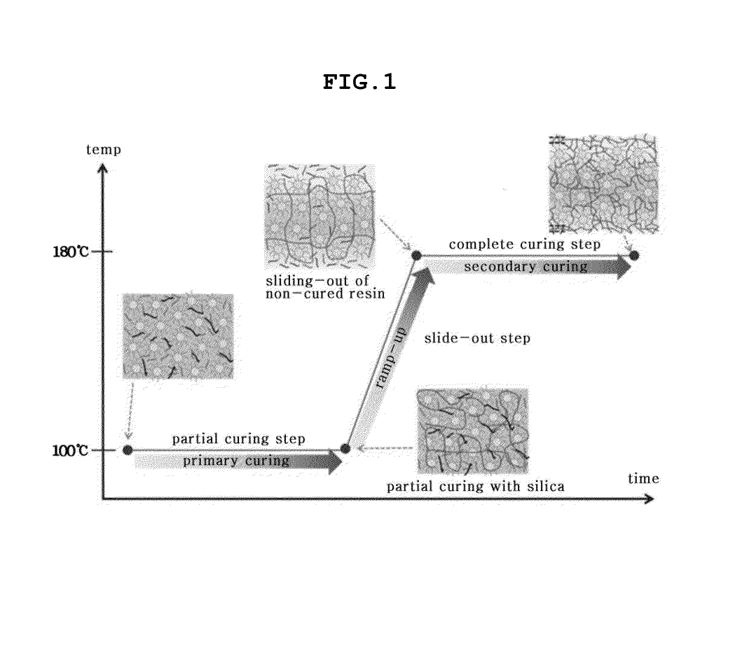

According to the present invention, as illustrated in FIG. 1, when two kinds of first and second epoxy resins having different curing starting temperatures are mixed and subjected to primary curing and secondary curing at a first curing temperature and a second curing temperature, respectively, the first epoxy resin having the low curing starting temperature (first curing temperature) is partially cured (primary curing), and the second epoxy resin having the high curing starting temperature (second curing temperature) is not cured, so that phase separation occurs between these two resins. Also, when secondary curing is further performed at a second curing temperature, the second epoxy resin is cured while sliding out on the surface of the film due to volume expansion at the increased temperature. As such, a surface skin layer which is an organic layer having a thickness of 10˜200 nm is formed on the inorganic filler (silica) distributed on the surface of the film. When the inorganic filler is silica surface-treated with a silane coupling agent, it may be chemically coupled with the epoxy group of the second epoxy resin, thus forming the surface skin layer which is structurally stable. Such a surface skin layer is not removed well in the subsequent desmearing process, and thus the case where silica is exposed to the surface of the film may be prevented. Thereby, adhesion to a Cu layer which is subsequently plated may be enhanced, and delamination of the plating layer may be prevented.

According to the present invention, the epoxy resin composition for an insulating film includes a thermosetting first epoxy resin having a curing starting temperature of 75˜100° C., a thermosetting second epoxy resin having a curing starting temperature of 100˜150° C., a first curing agent for the first epoxy resin, a second curing agent for the second epoxy resin, and silica surface-treated with a silane coupling agent, wherein the curing starting temperature of the first epoxy resin is lower than the curing starting temperature of the second epoxy resin, so that a desired skin layer and roughness may be obtained. Also, the epoxy resin composition may further include other additives.

The first epoxy resin is an epoxy resin having a low curing starting temperature, and the curing starting temperature thereof is 75˜100° C., and preferably 75˜85° C. The first epoxy resin may include one or more selected from the group consisting of a naphthalenic epoxy resin, a naphthol-phenolic epoxy resin, an olefinic epoxy resin, a diglycidyl ether of bisphenol A (DGEBA)-based epoxy resin having a molecular weight of 300 or less, and a diglycidyl ether of bisphenol F (DGEBF)-based epoxy resin having a molecular weight of 300 or less.

The second epoxy resin is an epoxy resin having a high curing starting temperature, and the curing starting temperature thereof is 100˜150° C., and preferably 120˜150° C. The second epoxy resin may include one or more selected from the group consisting of a cresol novolac epoxy resin, a bisphenol A epoxy resin (e.g. DEGEBA), and a rubber modified epoxy resin.

In the present invention, the first epoxy resin and the second epoxy resin may be selected without particular limitation so long as a difference in curing starting temperature between these two resins is at least 10° C. In order to attain high peel strength, such a temperature difference is preferably 40° C. or higher, more preferably 50° C. or higher, and even more preferably 60° C. or higher.

Each of the amounts of the first epoxy resin and the second epoxy resin may be 5˜15 wt %. If the amount of the first epoxy resin is less than 5 wt %, the thickness of the skin layer and the roughness may increase, but it is difficult to form a fine pattern. In contrast, if the amount thereof exceeds 15 wt %, it is difficult to form a roughness, undesirably weakening adhesion of a metal circuit. Thus, effects opposite to the addition effects of the first epoxy resin appear in the second epoxy resin. Furthermore, when the total amount of the epoxy resin increases, the amount of silica may comparatively decrease and thus CTE may increase.

Also, in the present invention, first and second curing agents respectively suitable for the kinds and the curing temperatures of the epoxy resins are used, so that the first epoxy resin and the second epoxy resin are efficiently cured to facilitate the formation of the surface skin layer. The first curing agent may be a triazine novolac curing agent having a secondary or tertiary amine group which does not induce a rapid curing reaction, and the second curing agent may be a phenol novolac curing agent to obtain desired reactivity. However, the first and second curing agents may be used without particular limitation so long as they enable thermosetting of the epoxy resins.

Each of the amounts of the first and second curing agents may be 5˜20 wt %. If the amount thereof is less than 5 wt %, a curing rate may decrease. In contrast, if the amount thereof exceeds 20 wt %, the curing agents may remain unreacted, undesirably increasing moisture absorption of the insulating film and thus deteriorating electrical properties.

According to the present invention, the resin composition includes silica as an inorganic filler to decrease CTE of the epoxy resin. The amount of the inorganic filler which decreases CTE in the resin composition may vary depending on the required properties in consideration of the end uses of the resin composition, but may be set to 50˜80 wt %. If the amount of the inorganic filler is less than 50 wt %, CTE may increase. In contrast, if the amount thereof exceeds 80 wt %, peel strength may decrease. The amount of the inorganic filler may be 60 wt % or more based on the solid content of the total resin composition.

Also in the case where the average particle size of silica exceeds 5 μm, it is difficult to stably form a fine pattern upon forming a circuit pattern on a conductor layer. Hence, the average particle size thereof is set to 5 μm or less. Furthermore, in order to increase moisture resistance and form a bond with an epoxy resin, silica should be surface-treated with a surface treatment agent such as a silane coupling agent. This silica is surface-treated with 0.5˜5 wt % of silane based on the weight of silica. If the amount of silane is less than 0.5 wt %, a surface skin layer is not formed well. In contrast, if the amount thereof exceeds 5 wt %, reactivity with the resin may increase and thus a surface skin layer is not formed well.

The epoxy resin composition according to the present invention may further include other additives typically used in the art, in addition to the above essential components. Examples of the additives include thickeners (e.g. asbestos, orben or benton), silicone-, fluorine- or polymer-based antifoaming agents, and/or leveling agents and adhesion enhancers (e.g. imidazole, thiazole, triazole or silane coupling agents). In addition, a colorant typically known and used in the art, such as phthalocyanine blue, phthalocyanine green, iodine green, disazo yellow, titanium oxide or carbon black may be used, as necessary.

The epoxy resin composition according to the present invention is prepared in the presence of an organic solvent. Taking into consideration the solubility and miscibility of the resins and the other additives used in the present invention, examples of the organic solvent may include, but are not particularly limited to, 2-methoxy ethanol, acetone, methylethylketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethylformamide, and dimethylacetamide.

In the method of manufacturing the insulating film for PCBs using the epoxy resin composition according to the present invention, a thermosetting first epoxy resin having a curing starting temperature of 75˜100° C., a thermosetting second epoxy resin having a curing starting temperature of 100˜150° C., a first curing agent for the first epoxy resin, a second curing agent for the second epoxy resin, and silica surface-treated with silane are mixed at the above weight ratio in the presence of an organic solvent, thus obtaining an epoxy resin composition.

The epoxy resin composition according to the present invention may be manufactured in the form of a dry film in a semi-solid phase using any process typically known in the art. For example, the resin composition may be formed into a film using a roll coater or a curtain coater, primarily cured at 75˜100° C., and then secondarily cured at 100˜150° C. As such, each of primary curing and secondary curing may be performed for 10˜40 min to achieve desired curing efficiency. The cured insulating film may be subjected to desmearing, and electroplating is then carried out, thus forming a circuit layer, thereby manufacturing a multilayer PCB.

The insulating film according to the present invention includes a bottom layer, and a surface skin layer having a thickness of 10˜200 nm formed on the bottom layer. If the thickness of the surface skin layer is less than 10 nm, adhesion to the Cu plating layer may decrease. In contrast, if the thickness thereof exceeds 200 nm, CTE may increase. Also, the insulating film is configured such that silica content of the surface skin layer is set to 60 or less, and preferably 40 or less as a weight ratio based on 100 of silica content of the bottom layer. Thereby, adhesion to the Cu plating layer may be enhanced, and defects such as delamination do not occur.

A better understanding of the present invention may be obtained via the following example and comparative example which are set forth to illustrate, but are not to be construed as limiting the present invention.

### Example 1

50 g of a naphthalene epoxy resin (SE-80) as a first epoxy resin, 50 g of a cresol novolac epoxy resin (YDCN-500˜01P, Kukdo Chemical) as a second epoxy resin, 38.20 g of an amino triazine-based novolac curing agent (PS-6313, Gun Ei Chemical Industry Co. Ltd.) having a concentration of 66.7 wt % as a first curing agent using a 2-methoxy ethanol solvent, and 51.62 g of a bisphenol A novolac curing agent (KBN-136) having a concentration of 66.7 wt % as a second curing agent using a 2-methoxy ethanol solvent were mixed, and the resulting mixture was stirred at 90° C. for 1 hr at 300 rpm. Subsequently, 296.97 g of spherical silica having a size distribution of 0.1˜1.2 μm and surface-treated with 1 wt % of a silane coupling agent based on the weight of silica was added, and the resulting mixture was stirred at 400 rpm for 3 hr. The temperature was decreased to room temperature, after which 1.25 g of 2-ethyl-4-methyl imidazole was added, and the resulting mixture was stirred for about 30 min, thus preparing an insulating material composition.

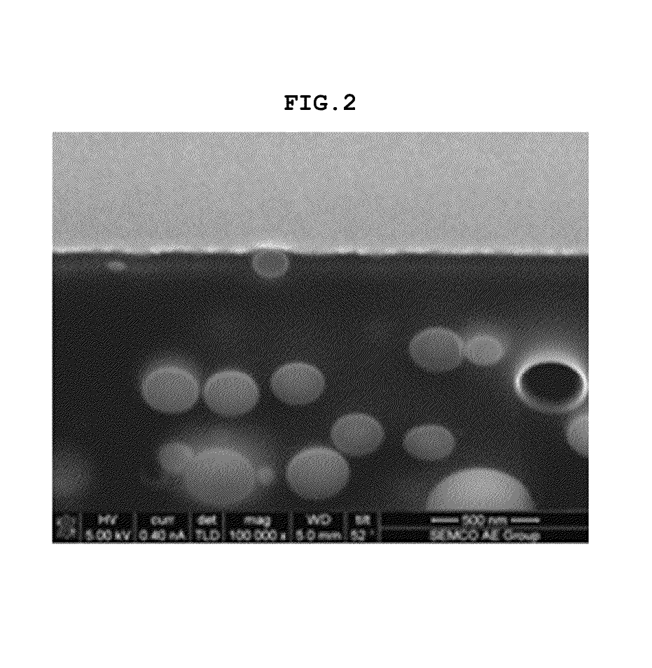

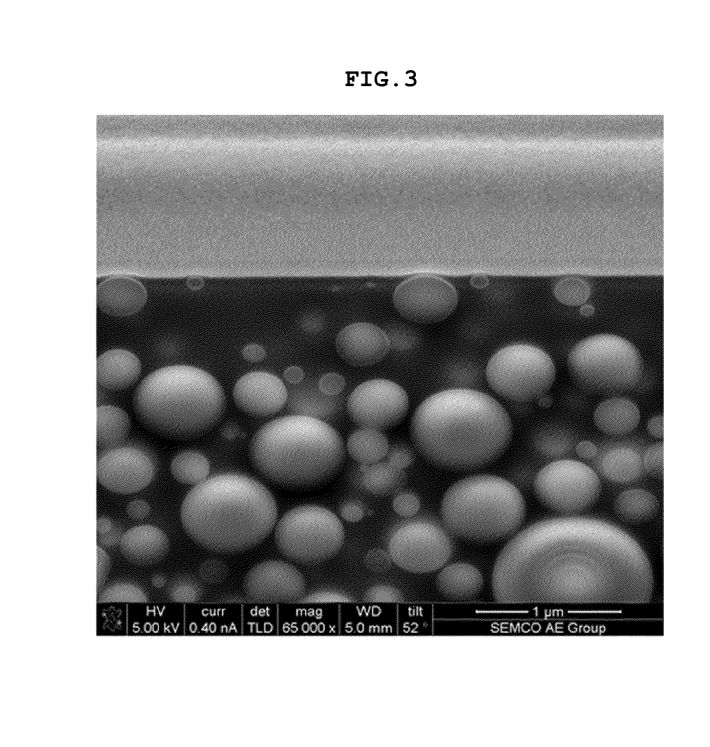

The insulating material composition was applied via film casting on a polyethylene terephthalate (PET) film, cut to a size of 405 mm×510 mm and then subjected to lamination at 100° C. Thereafter, primary curing at 100° C. for 30 min and secondary curing at 180° C. were performed, thus manufacturing an insulating film. The surface of the insulating film was observed with SEM. The results are shown in FIG. 2. The cross-section of the insulating film was observed with SEM. The results are shown in FIG. 3.

### Comparative Example 1

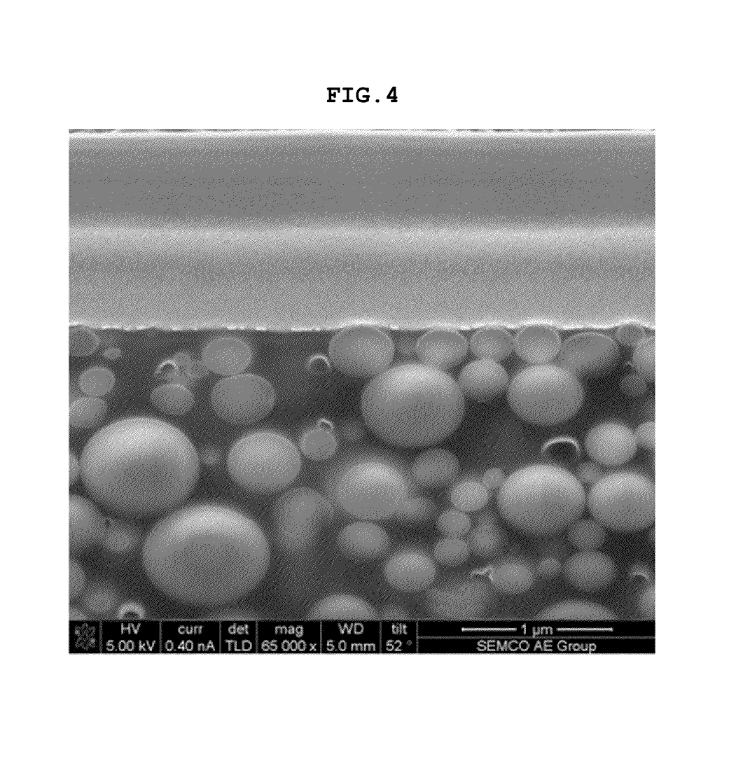

40 g of a naphthalene epoxy resin (SE-80), 40 g of a cresol novolac epoxy resin (YDCN-500˜01P, Kukdo Chemical), 20 g of a rubber modified epoxy resin (Struktol Polydis 3616), 71.60 g of an amino triazine-based novolac curing agent (PS-6313, Gun Ei Chemical Industry Co. Ltd.) having a concentration of 66.7 wt % using a 2-methoxy ethanol solvent, and 36.94 g of a thermoplastic resin (phenoxy) were mixed, and the resulting mixture was stirred at 90° C. for 1 hr at 300 rpm. Subsequently, 296.97 g of spherical silica having a size distribution of 0.1˜1.2 μm was added, and the resulting mixture was stirred at 400 rpm for 3 hr. The temperature was decreased to room temperature, after which 1.25 g of 2-ethyl-4-methyl imidazole was added, and the resulting mixture was stirred for about 30 min, thus preparing an insulating material composition. The insulating material composition was applied via film casting on a PET film, cut to a size of 405 mm×510 mm and then subjected to lamination at about 100° C. Thereafter, primary curing at 100° C. for 30 min and secondary curing at 180° C. were performed, thus manufacturing an insulating film. The cross-section of the insulating film was observed with SEM. The results are shown in FIG. 4.

The CTE of the insulating films of Example 1 and Comparative Example 1 and the silica content at a depth of 200 nm from the surface thereof were measured. The results are given in Table 1 below.

The measurement and evaluation of CTE were performed in such a manner that the resin composition film was subjected to thermosetting at 190° C. for 2 hr thus releasing the support, thereby obtaining a cured sheet, which was then cut to a test sample having a width of 4 mm and a length of about 24 mm, followed by conducting thermomechanical analysis using a thermomechanical analyzer (TMA) via tension testing. The test sample was mounted onto the analyzer, and two measurements were continuously carried out at a heating rate of 5° C./min. Upon both measurements being taken, average linear CTE (ppm) between 50° C. and 100° C. was calculated as CTE (α 1, Tg or less).

The silica content at a depth of 200 nm from the surface was determined by analyzing the cross-section using FIB (Focused Ion Beam) and then measuring the area of spherical silica using image analysis.

TABLE 1

| | | | Curing | Pre-curing | | CTE | |
|---|---|---|---|---|---|---|---|
| | Component | | starting | Temp.(° C.) | | (α1, | Surface silica |
| | Epoxy | Curing agent | Temp.(° C.) | 1^{st} | 2^{nd} | ppm/° C.) | content (%) |
| Ex. 1 | Cresol novolac | Bisphenol A | 150 | 100 | 180 | 23 | 35 |
| | | novolac | | | | | |
| | Naphthalene | Amino triazine | 80 | | | | |
| | | novolac | | | | | |
| Comp. | Cresol novolac | Amino triazine | 110 | 100 | 180 | | 65 |
| Ex. 1 | Naphthalene | novolac | 80 | | | | |
| | Rubber modified | | 95 | | | | |

As is apparent from Table 1 and FIGS. 2 to 4, the insulating film of Example 1 had the same CTE as that of Comparative Example 1, but the silica content of the surface layer was much smaller in Example 1 (FIGS. 2 and 3) than in Comparative Example 1 (FIG. 4), thus obtaining superior results. As such, peel strength of Example 1 was 0.6 kgf/cm, which is evaluated to be far superior compared to 0.4 kgf/cm of Comparative Example 1. Therefore, the insulating film according to the present invention can be appropriate for use in a substrate. As described hereinbefore, the present invention provides an epoxy resin composition for an insulating film, an insulating film, and a PCB including the insulating film. According to the present invention, the insulating film for a multilayer PCB using a build-up process, manufactured from the epoxy resin composition of the invention, can include a surface skin layer having a thickness of 10˜200 nm and containing a comparatively small amount of inorganic filler, and can have a hemispherical roughness having a diameter of hundreds of nm˜approximately 1 μm. Thereby, peel strength can be improved, thus enabling the formation of a fine circuit, and CTE of the insulating film can be low, thus preventing the deformation of the film.

Although the embodiments of the present invention have been disclosed for illustrative purposes, those skilled in the art will appreciate that a variety of different modifications, additions and substitutions are possible, without departing from the scope and spirit of the invention as disclosed in the accompanying claims.

Accordingly, such modifications, additions and substitutions should also be understood as falling within the scope of the present invention.

What is claimed is:

1. An epoxy resin composition for an insulating film, comprising:
a thermosetting first epoxy resin having a curing starting temperature of 75˜100° C.;
a thermosetting second epoxy resin having a curing starting temperature of 100˜150° C.;
a first curing agent for the first epoxy resin;
a second curing agent for the second epoxy resin; and
a silica surface-treated with a silane coupling agent,
wherein the curing starting temperature of the first epoxy resin is lower than the curing starting temperature of the second epoxy resin.

2. The epoxy resin composition of claim 1, wherein the epoxy resin composition comprises 5˜15 wt % of the first epoxy resin, 5˜15 wt % of the second epoxy resin, 5˜20 wt % of the first curing agent, 5˜20 wt % of the second curing agent, and 50˜80 wt % of the silica surface-treated with the silane coupling agent.

3. The epoxy resin composition of claim 1, wherein the curing starting temperature of the first epoxy resin is 75˜85° C., and the curing starting temperature of the second epoxy resin is 120˜150° C.

4. The epoxy resin composition of claim 1, wherein the first epoxy resin comprises one or more selected from the group consisting of a naphthalenic epoxy resin, a naphthol-phenolic epoxy resin, an olefinic epoxy resin, a diglycidyl ether of bisphenol A (DGEBA)-based epoxy resin having a molecular weight of 300 or less, and a diglycidyl ether of bisphenol F (DGEBF)-based epoxy resin having a molecular weight of 300 or less, and the second epoxy resin comprises one or more selected from the group consisting of a cresol novolac epoxy resin, a bisphenol A epoxy resin, and a rubber modified epoxy resin.

5. The epoxy resin composition of claim 1, wherein a difference in the curing starting temperature between the first epoxy resin and the second epoxy resin is 10˜70° C.

6. The epoxy resin composition of claim 1, wherein the first curing agent is a triazine novolac curing agent having a secondary or tertiary amine group, and the second curing agent is a phenol novolac curing agent.

7. The epoxy resin composition of claim 1, wherein the silica surface-treated with the silane coupling agent is obtained by surface-treating silica with 0.5˜5 wt % of silane based on a weight of the silica.

8. A method of manufacturing an insulating film for a printed circuit board, comprising:
mixing a thermosetting first epoxy resin having a curing starting temperature of 75˜100° C., a thermosetting second epoxy resin having a curing starting temperature of 100˜150° C., a first curing agent for the first epoxy resin, a second curing agent for the second epoxy resin, and a silica surface-treated with silane, thus preparing an epoxy resin composition;
forming the composition into a film, and performing primary curing at 75˜100° C. and secondary curing at 100˜150° C.; and
subjecting the film to desmearing to form a roughness.

9. The method of claim 8, wherein each of the primary curing and the secondary curing is performed for 10˜40 min.

10. The method of claim 8, wherein the epoxy resin composition comprises 5˜15 wt % of the first epoxy resin, 5˜15 wt % of the second epoxy resin, 5˜20 wt % of the first curing agent, 5˜20 wt % of the second curing agent, and 50˜80 wt % of the silica surface-treated with silane.

11. The method of claim 8, wherein the curing starting temperature of the first epoxy resin is 75˜85° C., and the curing starting temperature of the second epoxy resin is 120˜150° C.

12. The method of claim 8, wherein the first epoxy resin comprises one or more selected from the group consisting of a naphthalenic epoxy resin, a naphthol-phenolic epoxy resin, an olefinic epoxy resin, a diglycidyl ether of bisphenol A (DGEBA)-based epoxy resin having a molecular weight of 300 or less, and a diglycidyl ether of bisphenol F (DGEBF)-based epoxy resin having a molecular weight of 300 or less, and the second epoxy resin comprises one or more selected from the group consisting of a cresol novolac epoxy resin, a bisphenol A epoxy resin, and a rubber modified epoxy resin.

13. The method of claim 8, wherein a difference in the curing starting temperature between the first epoxy resin and the second epoxy resin is 10˜70° C.

14. The method of claim 8, wherein the first curing agent is a triazine novolac curing agent having a secondary or tertiary amine group, and the second curing agent is a phenol novolac curing agent.

15. The method of claim 8, wherein the silica surface-treated with silane is obtained by surface-treating silica with 0.5˜5 wt % of silane based on a weight of the silica.

16. An insulating film for a printed circuit board, comprising a bottom layer, and a surface skin layer formed to a thickness of 10˜200 nm on the bottom layer, wherein a silica content of the surface skin layer is 60 or less as a weight ratio based on 100 of a silica content of the bottom layer.

17. The insulating film of claim 16, wherein the silica content of the surface skin layer is 40 or less as a weight ratio based on 100 of the silica content of the bottom layer.

18. A printed circuit board, including the insulating film of claim 16.
